(19) United States
(12) Patent Application Publication
(10) Pub. No.: US 2019/0094288 A1
(43) Pub. Date: Mar. 28, 2019

(54) ACCURACY OF EVENT LOCATING ON POWERLINES BASED ON FIELD DATA

(71) Applicant: Schweitzer Engineering Laboratories, Inc., Pullman, WA (US)

(72) Inventor: Edmund O. Schweitzer, III, Pullman, WA (US)

(73) Assignee: Schweitzer Engineering Laboratories, Inc., Pullman, WA (US)

(21) Appl. No.: 16/139,715

(22) Filed: Sep. 24, 2018

Related U.S. Application Data
(60) Provisional application No. 62/562,284, filed on Sep. 22, 2017.

(51) Int. Cl. G01R 31/08; H02H 7/26

(52) U.S. Cl. CPC G01R 31/088; G01R 31/085; H02H 7/265

(57) ABSTRACT

An intelligent electronic device (IED) may detect arrival times and/or other characteristics of traveling waves and/or reflections thereof to determine a distance to a fault location in terms of per-unit length. An IED may convert between line distances, line-of-sight distances, straight-line distances, and/or terrain-based distances. An IED may refine one or more physical line parameters used for traveling wave-based location calculations for iterative improvements in accuracy. For instance, an IED may compare reported distances to fault locations with field-verified, confirmed fault locations to refine physical line parameters used in future location calculations. Similarly, an IED may identify which of a plurality of towers corresponds to a fault location based on a mapping of towers on a per-unit scale. Confirmed fault locations may be used to update or refine the mapping to improve future tower identification relative to per-unit fault location.

### RELATED APPLICATION

This application claims priority under 35 U.S.C. § 119 to U.S. Provisional Patent Application No. 62/562,284 filed on Sep. 22, 2017, titled “Electric Power System Event Locating Using Traveling Wave and Field Data,” which application is hereby incorporated by reference in its entirety.

### TECHNICAL FIELD

This disclosure relates to determining a location of an event, such as a fault, by analysis of traveling wave and field data. More specifically, this disclosure relates to improving the accuracy of event localization utilizing confirmed locations of past events.

### BRIEF DESCRIPTION OF THE DRAWINGS

This disclosure includes illustrative embodiments that are non-limiting and non-exhaustive. Reference is made to certain of such illustrative embodiments that are depicted in the figures described below.

FIG. 1 illustrates a block diagram of a system for detecting a traveling wave and calculating a location of a fault using the detected traveling wave consistent with certain embodiments of the present disclosure.

FIG. 2 illustrates a side view of one example of an overhead transmission line in an electric power delivery system.

FIG. 3 illustrates a mapping of a tower position on a per-unit location scale between two terminals, according to one embodiment.

FIG. 4 illustrates a repositioning of a single tower based on a confirmed fault location on the per-unit location scale between two terminals, according to one embodiment.

FIG. 5 illustrates a repositioning of a number of towers based on a confirmed fault location on the per-unit location scale between two terminals, according to one embodiment.

FIG. 6 illustrates an example table of towers, physical locations, and per-unit distances before and after a confirmed fault.

FIG. 7 illustrates a functional block diagram of a fault location system that uses confirmed fault locations as feedback to refine parameters and/or tower locations on a per-unit scale.

FIG. 8 illustrates an example table of original and refined per-unit mapping of towers, according to one embodiment.

FIG. 9 illustrates a simplified representative diagram of an overhead transmission line in an electric power system including tower positions.

FIG. 10A illustrates an example table of original and refined tower positions, according to one embodiment.

FIG. 10B illustrates a simplified diagram of tower positions based on original or default position data in the table of FIG. 8.

FIG. 10C illustrates an exaggerated diagram of the repositioned tower locations corresponding to the data in the table of FIG. 8.

### DETAILED DESCRIPTION

Systems and methods are described herein for improving the effective accuracy of fault locating. Many of the embodiments described herein may be implemented by one or more intelligent electronic devices (IEDs) in conjunction with traveling wave analysis. In various embodiments, an IED may map a one-dimensional output from an electrical-based fault locator into the physical world of transmission towers. Inspection and repair crews rely on calculated (or estimated) fault locations to efficiently find, maintain, and repair powerlines.

An IED may function as a fault locator utilizing impedance-based and/or traveling wave-based algorithms to calculate fault locations. However, many real-world conditions complicate the mapping of calculated fault locations to real-world tower locations. The presently described systems and methods utilize prior, confirmed fault locations to improve subsequent fault localization.

Fault locators may utilize electrical measurements to estimate (calculate) fault locations on a transmission line. For example, a fault locator may calculate a fault location using impedance-based approaches that rely on fundamental frequency current and voltage measurements. In contrast, fault locators that calculate fault locations using traveling wave-based approaches may rely on the arrival times of traveling waves. In some embodiments, fault locators may utilize high-fidelity voltage signals from incident waves to calculate fault locations.

In both impedance-based and traveling-wave-based fault locators, the measurements are taken at line terminals, such as at power substations. Some fault locators may utilize measurements from one end of the line (i.e., using a single-ended method), while other fault locators may utilize measurements from both (or all) ends of the line (i.e., using double-ended or multi-ended methods).

Impedance-based fault locators have limited accuracy. A single-ended fault locator may only be accurate to within a small percentage of the line length. For a long line, such as a 200-kilometer-long line, a ±5 percent error corresponds to a 20-kilometer interval of uncertainty. In an embodiment in which towers are located every 300 meters, an inspection or repair crew may be deployed to search for the fault on a span of more than 66 towers (20 kilometers/300 meters). Double-ended impedance-based fault locators are more accurate. However, even with a ±1 percent error, the margin of error may still correspond to many tower spans.

Traveling-wave-based fault locators are much more accurate. Typically, they can locate faults to within one or two tower spans. The double-ended traveling wave fault location equations can be expressed as:

$$M = \frac{1}{2} [ 1 + \frac{{t}_{S} - {t}_{R}}{T} ] \cdot L \qquad Eq . 1$$

In Equation 1, M is the distance to the fault in kilometers (miles could alternatively be used), L or the “L parameter” is the total line length in kilometers, t_{S}−t_{R}, is the difference in arrival time of the initial traveling waves from the fault at the two terminals (S and R) of the line in microseconds, T is the time, in microseconds, that it takes for a traveling wave to travel from one end of the line to the opposite end of the line (i.e., the total line propagation time).

A single-ended traveling wave fault locator at terminal S can also calculate a reasonably accurate distance to a fault event using Equation 2 below:

$$M = \frac{1}{2} [ \frac{{t}_{S 2} - {t}_{S 1}}{T} ] \cdot L \qquad Eq . 2$$

Again, in Equation 2, M is the distance to the fault in kilometers (miles could alternatively be used), L is the total line length in kilometers, t_{S2} is the arrival time of the first traveling wave reflection from the fault at the S terminal, and t_{S1} is the arrival time of the initial traveling wave from the fault at the S terminal, T is the time, in microseconds, that it takes for a traveling wave to travel from one end of the line to the opposite end of the line (i.e., the total line propagation time).

The relationships expressed in Equations 1 and 2 can be expressed as presented Equation 3 below, where m is the per-unit distance to the fault.

M=m·L Eq. 3

Equations 1 and 2 can both be expressed in terms of per-unit distance to the fault, m, instead of in terms of absolute distance, M. A double-ended fault location system can utilize Equation 4 to calculate the per-unit distance to the fault, m, based on the difference in the arrival times of the traveling waves from the fault at the two terminals (S and R).

$$m = \frac{1}{2} \cdot ( 1 + \frac{{t}_{S} - {t}_{R}}{T} ) \qquad Eq . 4$$

Alternatively, a single-ended fault location system can utilize Equation 5 to calculate the per-unit distance to the fault, m, based on a difference between the arrival time of the first reflection from the fault at the S terminal and the arrival time of the initial traveling wave from the fault at the S terminal.

$$m = \frac{1}{2} \cdot ( \frac{{t}_{S 2} - {t}_{S 1}}{T} ) \qquad Eq . 5$$

One or more IEDs using one or more traveling wave detection algorithms may locate a fault within a one-tower span or better. A fault-locating IED may, for example, determine a distance to a fault based on the arrival time of one or more traveling waves caused by a fault event. The IED may relate the distance to the total line length expressed in terms of the time it takes for a traveling wave to travel from one end of the line to the opposite end of the line. This time is referred to as the traveling wave line propagation time (TWLPT), or as expressed in Equations 1-5 and throughout this remainder of this disclosure, the “T parameter” or simply “T.”

A fault-locating IED may convert a time-based distance (e.g., a per-unit distance, m) to a physical distance in miles or kilometers using a known line length (L parameter), and using the principle of proportionality expressed in Equation 3. The electrical-based fault location methods, including traveling wave-based methods, natively calculate fault location in per-unit. Conversion of the fault location in per-unit to physical distance historically assumes a straight-line mapping or conversion between the electrical per-unit distance and the physical distance. This historical mapping approach was sufficiently accurate when relatively inaccurate impedance-based fault locators were utilized. However, the potential benefits of significantly more accurate traveling wave-based fault locators are lost due to inaccurate field data and historically simplistic mapping approaches.

Calculation of the per-unit fault location, m, using Equations 4 and 5 is based on the ratio of time measurements for traveling waves from a fault and a T parameter. Equations 4 and 5 can produce highly accurate per-unit fault location calculations, m, because the input data can be determined with a high level of accuracy. For example, an IED may calculate Δt=t_{S}−t_{R} with a 1 μs error while T for a 200 km-long line is about 700 μs. Equation 4 can be used to calculate a fault location with a potential accuracy on the order of 150 meters (0.5*(1+Δt/700)−0.5*(1+(Δt+1)/700)=0.00071 per-unit, or 0.00071*200,000 meters=142 meters).

However, it may be difficult to measure the physical line length, (L parameter) and/or the L parameter may even change over time due to sag and other environmental factors. Assuming that the length is known within a margin of error of 2%, a line having a nominal length of 200 kilometers may have an actual length of 204 kilometers. A fault locator may calculate, with a high level of accuracy, a fault location as 0.800 per-unit. Based on the assumed 200-kilometer line length, the fault locator may identify a fault location as being 160 kilometers from the terminal (0.800*200 km=160 km). Given that the line is actually 204 kilometers long, the fault location is actually 163.2 kilometers from the terminal, a 3.2 km error.

Even though the double-ended traveling wave fault location method has a potential accuracy of 150 meters, the fault locator produced a result that was incorrect by more than 3,000 meters. The error is largely due to the lack of accurate line length data.

With traveling wave-based fault locators, the non-homogeneous relationship between the electrical distance and the physical distance has a practical impact on the effective accuracy of fault localization. A traveling wave-based fault locator may calculate a highly accurate per-unit fault location. The fault locator may provide a distance-converted fault location to a repair crew. The repair crew may associate the provided fault location with the nearest tower. Given the known limitations of mapping the electrical distance to the physical distance, the repair crew may be required to search several nearby towers to find the actual location of the fault. The difference between the provided fault location and the confirmed fault location may be labeled a fault location error. However, as previously noted, a large portion of the fault location error does not come from the error in the per-unit electrical fault location, but rather from the association of a specific physical tower to the calculated per-unit electrical fault location.

The “distance” between two devices in an electrical power delivery system may be measured in different ways. For example, different measurement approaches may be used to measure the distance between two towers supporting an electrical line, the distance between two insulators on the line, the distance between two IEDs associated with the line.

For example, one distance may be the conductor length between two towers. The conductor length corresponds to the actual length of the power conductors and depends on, for example, the sag of the power conductors. The sag may change with ambient temperature, wind speed, wind direction, other environmental conditions, line loading, and/or other general “operational conditions” that affect the T parameter of the physical line.

Another distance between two towers may be a line-of-sight distance between two consistent points on the tower, such as the mounting points between the conductor and the supporting insulator. This distance could be measured, for example, by using a laser range finder. Although less accurate, a line-of-sight distance might also be determined based on satellite or aerial images, assuming that elevation changes are also taken into account.

Yet another distance between, for example, two towers may be a straight-line distance between two consistent points on the tower, such as the mounting points between the conductor and the supporting insulator on a two-dimensional plane. Finally, another distance may be a terrain-distance. A terrain-distance may be an actual distance between two consistent points on the tower, such as the center of the tower base, or the corner of the tower base, traveled on the earth's surface by, for example, a foot patrol beneath a conductor as the foot patrol walks or drives between the two towers.

According to various embodiments, a fault locator, or other IED, may utilize historical fault calculation data and confirmed tower locations to improve future mappings of electrical per-unit distance calculations to physical tower locations. In some embodiments, a comparison of electrical per-unit distance calculations with confirmed tower locations may be used to update or modify one or more physical line parameters used by the fault locator. For example, an IED may update the L parameter. The IED may use the adjusted parameters to more accurately map future electrical per-unit distance calculations to physical line locations (e.g., towers).

In some embodiments, an IED may utilize historical electrical per-unit distance calculations and confirmed tower locations to generate a mapping therebetween. The IED may interpolate between confirmed data points to develop a functional mapping between electrical per-unit distances and tower locations (e.g., GPS coordinates of towers). The mapping may be programmed as a post-processing task in SCADA software, for example.

That is, a tower location may be “repositioned” on the per-unit scale based on confirmed distances to fault locations. Once a given tower on a transmission line has been “repositioned,” other towers on the transmission line may be “repositioned” by a proportional distance. The adjusted positions of the tower locations on the per-unit scale will allow for improved accuracy of future fault location determinations. To be clear, “repositioning” a tower comprises digitally repositioning the tower by assigning new location data to the tower on a per-unit scale.

As used herein, an IED may refer to any microprocessor-based device that locates faults, monitors, controls, automates, and/or protects monitored equipment within a power system. Such devices may include or be embodied as, for example, line protective relays, feeder relays, bay controllers, meters, computing platforms, programmable logic controllers (PLCs), programmable automation controllers, human machine interfaces (HMI) and the like. The term IED may be used to describe an individual IED or a system comprising multiple IEDs. An IED may be said to be processor-based, perform calculations, and the like, even though the IED may rely on cloud-based or server-based processing power available via a communication network.

Additional understanding of the embodiments of the present disclosure can be gained by reference to the drawings, wherein like parts are designated by like numerals throughout. It will be readily understood that the components of the disclosed embodiments, as generally described and illustrated in the figures herein, could be arranged and designed in a wide variety of different configurations. Thus, the following description of the embodiments of the systems and methods of the disclosure is not intended to limit the scope of the disclosure, as claimed, but is merely representative of possible embodiments of the disclosure. In addition, the steps of a method do not necessarily need to be executed in any specific order, or even sequentially, nor need the steps be executed only once, unless otherwise specified or contextually required.

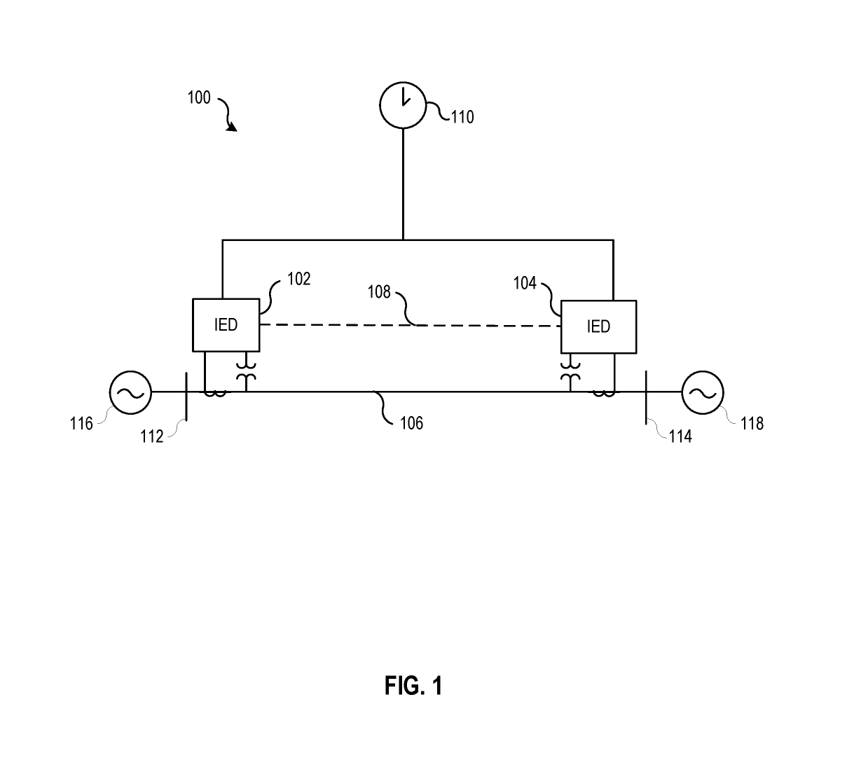

FIG. 1 illustrates a block diagram of a system 100 for detecting and calculating a location of a fault using traveling wave principles and elements further described herein, some of which are known in the art. System 100 includes a conductor 106, such as a transmission line, connecting two nodes, which are illustrated as a local terminal 112 and a remote terminal 114. Local and remote terminals 112 and 114 may be buses in a transmission system supplied by one or more power sources, such as one or both of generators 116 and 118.

Although illustrated in single-line form for purposes of simplicity, system 100 may be a multi-phase system, such as a three-phase electric power delivery system. A data communication channel 108 may allow IEDs 102 and 104 to exchange information relating to, among other things, voltages, currents, time-domain fault detection and location. Many of the approaches described herein assume or rely on accurate knowledge of physical line property parameters to determine accurate location data for a fault or other event. Various techniques may be used to accurately determine or refine electric power system physical line parameters. Examples of such techniques are described in the Appendix filed with U.S. Provisional Application 62/562,284, to which this application claims priority. Additional examples and techniques are described in U.S. patent application Ser. No. 15/884,707 filed on Jan. 31, 2018 titled “Traveling Wave Based Single End Fault Location,” which is hereby incorporated by reference in its entirety.

Using any of these or other known techniques, traveling waves may be used to calculate or refine the propagation time parameter of an electric power system line or line section. In many instances, a fault (or other system event inducing a traveling wave) may be cleared or repaired by one or more field technicians. Accurate event location information may be used to direct a field crew to the correct location for repairs. Location identification information that is inaccurate, by even a small percentage, may result in crews searching for faults along many kilometers of a powerline and/or numerous towers.

Although the propagation time of a traveling wave along a line or line section is a directly measurable parameter, directing a crew to a corresponding physical location in the real world is non-trivial. As described above, the distance between two devices, such as two towers, insulators, relays, or terminal devices may be measured in different ways. This distance may have one value at the time of installation or at a specific date when measurements are made. However, the line distance may change with ambient temperature, line loading, and other environmental or installation conditions (collectively referred to as “operational conditions”). A straight-line distance on a two-dimensional map, satellite image, or aerial image may be adequate if elevation is generally constant. Finally, a terrain-distance may be helpful if a crew is navigating to an identified fault location using a terrestrial vehicle or on a foot patrol.

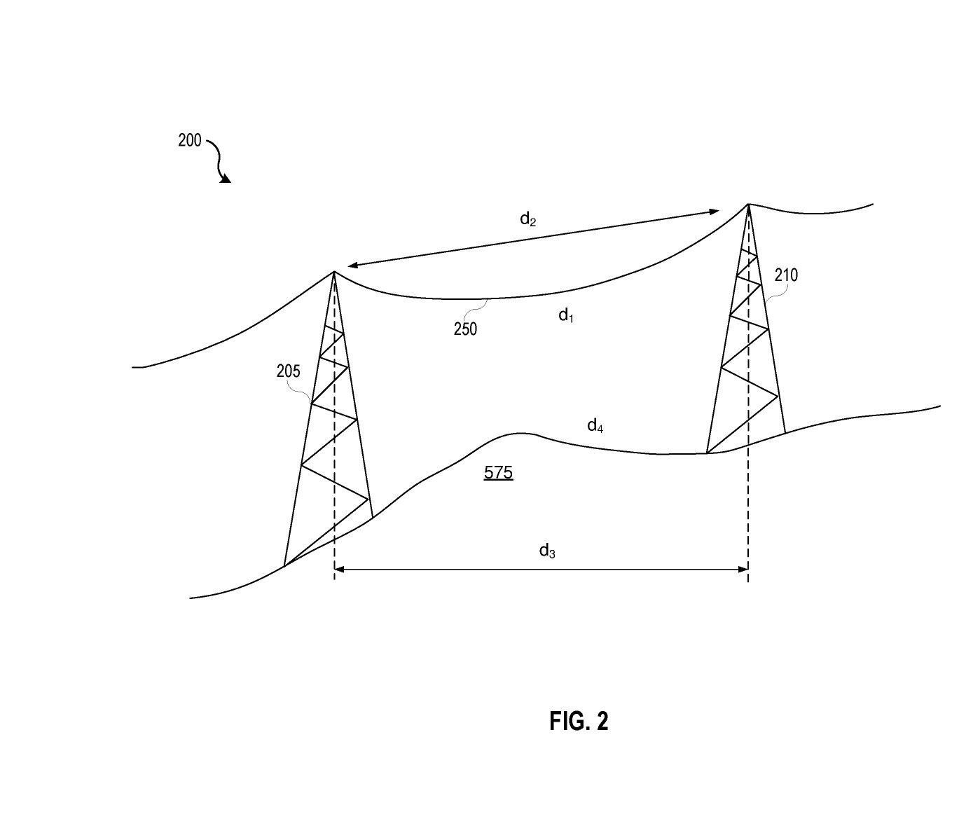

FIG. 2 illustrates a simplified side view of a section of a transmission line in an electric power delivery system 200, including two towers 205 and 210 and a span of conductor 250 between the towers 205 and 210. Four different distances between the towers are illustrated. Distance d1 is the actual length of the power conductor(s).

The distance d1 depends on the sag in the line and may change with conductor temperature, line loading, and ambient conditions, such as temperature and wind. The distance d1 is the most accurate measure of the distance traveling waves from a fault or other event travel. Traveling waves propagate as electromagnetic waves in the space between and around the conductors and not necessarily along the conductors. Although the distance d1 can be electrically measured in terms of the corresponding TW propagation time, it is difficult to measure in terms of physical length and it may change based on line loading, installation conditions, and environmental conditions.

Distance d2 is shown in FIG. 2 as the line-of-sight distance between the insulators at towers 205 and 210. This distance is fixed and partially reflects the terrain elevation, but it neglects the sag in conductor 250. Distance d3 is the straight-line distance such as between the centers of the towers 205 and 210 neglecting terrain elevation. The straight-line distance, d3, may be measured using two-dimensional plane such as mapping data, satellite images, aerial images, or overhead flight distance measurements (e.g., by manned or unmanned aircraft flying at a fixed altitude). Finally, d4 is the distance between towers 205 and 210 measured on the terrain surface, as might be measured by an odometer of a terrestrial-based vehicle or a foot patrol.

The differences between d₁, d₂ d₃, and d₄ can be significant depending on the sag and terrain. A power line may include tens or hundreds of tower spans (2-3 spans per km of length). A line length calculated by summing the d₁ values for all the tower spans between the line terminals will be different than the line length obtained by summing the d₂ or d₃ values. The difference may be several percent. While the d2, d3 and d4 distances are fixed, normal, operating, and environmental variations may modify the distance, d₁, by a fraction of a percent.

These “distance uncertainties” are described above in the context of the entire line length between the first line terminal and the opposite line terminal. However, the same distance uncertainties make it difficult to accurately define a distance from a line terminal to any given tower along the line. That is, it is difficult to accurately measure or calculate the linear distance from a line terminal to a tower with precision congruent with the precision of the traveling wave fault locators.

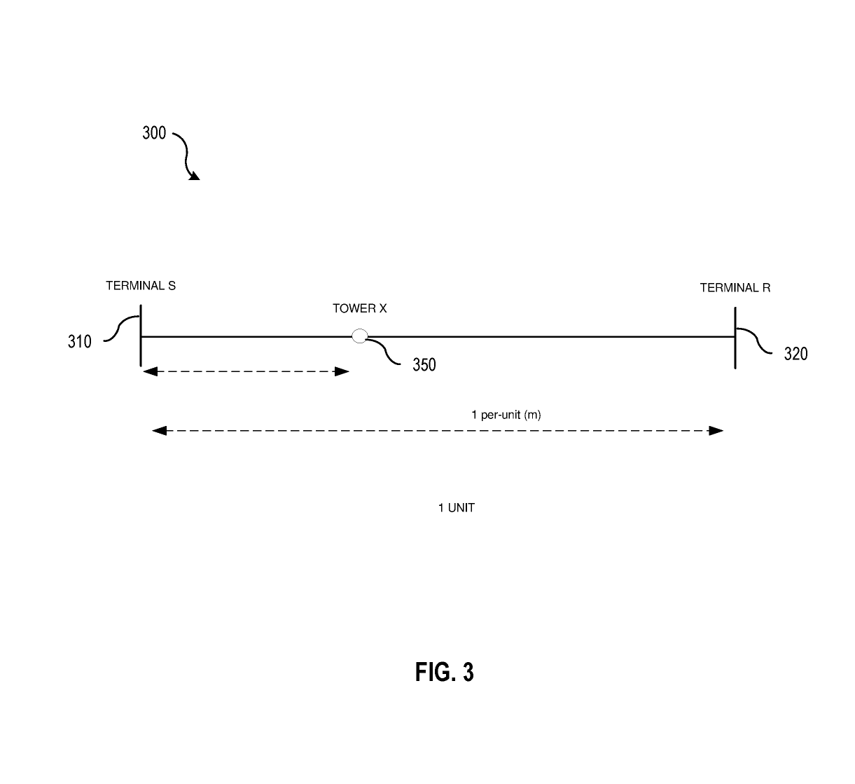

FIG. 3 illustrates a “mapping” 300 of a position of a Tower X 350 on a per-unit location scale between Terminal S 310 and Terminal R 320, according to one embodiment. A more complete mapping of a real-world system can be generated to include a linear one-dimensional output from the electrical-based fault locator with the two ends being the line terminals and the towers as points on that linear scale. Each tower may be labeled with its unique identification and physical location, such as GPS coordinates, or a distance from a landmark (e.g., a distance from an intersection, milepost on a highway, etc.).

The systems and methods described herein allow for an initial mapping of fault locations calculated in electrical-based per-unit distance and the geospatial locations of towers along the electrical line. As described above, converting between per-unit electrical distance, m, and the physical distance, M, using the linear relationship in Equation 3 does not provide a congruently accurate result because the total line length is not known, or perhaps even knowable, with congruent accuracy.

The systems and methods described herein may be embodied within or implemented by a single IED, such as a relay or fault locator device. However, in many instances the systems and methods described herein are more easily implemented within a centralized control system, such an energy management system (EMS) or supervisory control and data acquisition (SCADA) system. Regardless of the specific hardware implementation, the system may store mapping data for one or more electrical lines in terms of per-unit electrical line length between two terminals. The mapping data may include data for all the towers between the two terminals including, for example, tower identification numbers, geospatial tower location information (e.g., GPS coordinates or landmark-reference location data), and per-unit location data. For example, a tower located at the midpoint of the electrical line length is described as being located at m=0.5.

Conceivably, the per-unit location data for each tower could be actually measured by deenergizing the lines, sequentially shorting conductor(s) at each tower, generating relatively high impulse source pulses, and measuring echo arrival times from each sequentially shorted tower. This time domain reflectometry (TDR) approach would be very time consuming, require a first crew operating the impulse source, and require a second crew moving from tower to tower to apply, remove, and relocate the temporary shorts after each measurement. As may be readily appreciated, actually measuring the per-unit location data of each tower may not be possible or practical in real world systems. The systems and methods described herein use confirmed fault locations to update, or even continually refine, initial per-unit fault location estimates of each tower.

The system may process the raw output of a fault locator (e.g., an output from a double-ended traveling wave-based fault locator) and return the physical location of a fault to a human operator. The system may be adapted as desired by the operators to return the physical location of the fault in terms of any of the line length. The system may additionally or alternatively indicate the physical location of a fault by identifying the nearest tower.

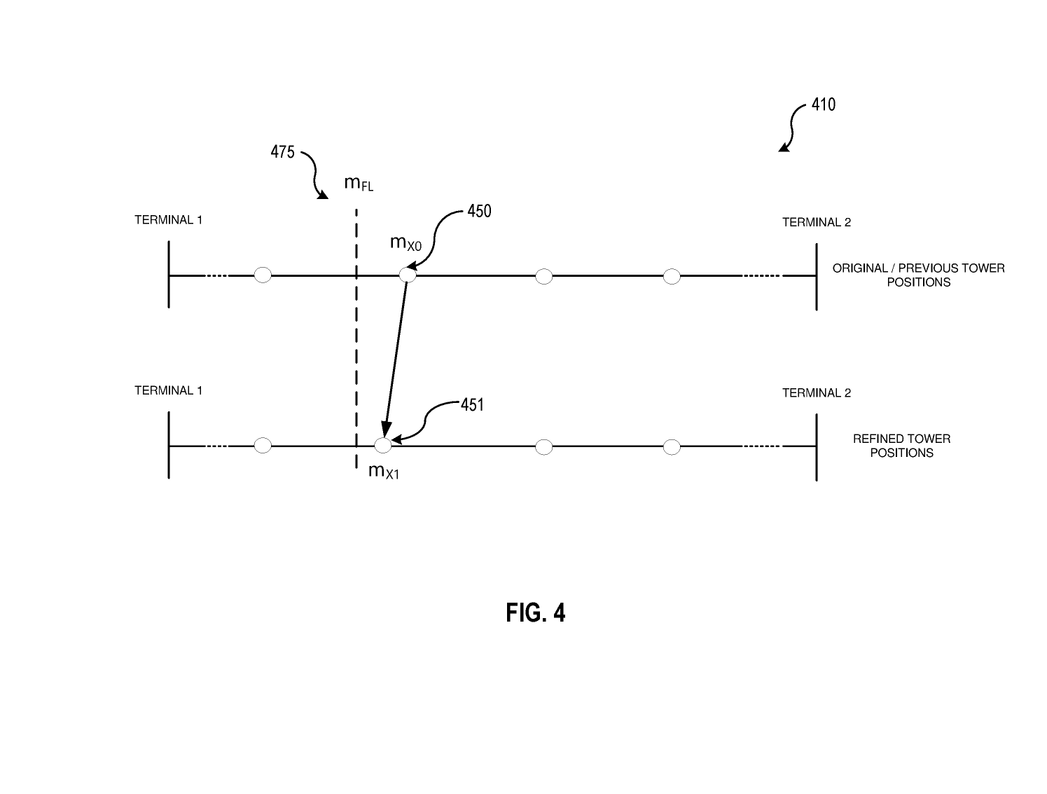

FIG. 4 illustrates a repositioning of a single tower being moved from an initial position 450 to an updated position 451 based on a confirmed fault at a location 475 on the per-unit location scale 410 between two terminals. When a fault occurs on the line, a protection system may trip breakers within a few tens of milliseconds. A fault locator may calculate a distance to the fault, M_{FL}, and communicate it within a few seconds. A crew may be dispatched to find and repair the faulted system. Depending on the urgency and specific attributes of the physical system, the human operators may confirm the fault at a geospatially identified location, M_{CONFIRMED} in terms of the tower identification number within some number of minutes, hours, or days. Eventually, the geospatially identified location of the fault, M_{CONFIRMED}, is returned to an internal database of past events.

A geospatially identified location, M_{CONFIRMED}, may include one or more of a GPS location, tower coordinates, tower identification number. The system may auto-calibrate key settings or parameters used by IEDs or fault locators. The system may also update or refine the mapping of one or more tower positions relative to the per-unit electrical location scale between the terminals, thereby enabling the next fault to be located with even higher accuracy.

With reference to Equations 1 and 4, the difference between the arrival time of the first reflection from the fault at the S terminal and the arrival time of the initial traveling wave from the fault at the S terminal (the t_{S}−t_{R} term in Equation 4), can be represented by as simply At. A fault locator using Equation 4 to calculate a fault location, M_{FL}, does so in reliance on an accurate T parameter (TWLPT). Once a confirmed fault location, M_{CONFIRMED}, is provided by a line crew, the system may automatically calibrate the fault-locating equation. First, the system may calculate the per unit fault locator M_{CONFIRMED} based on the M_{CONFIRMED}, using the best-known estimate of the distance from the tower given by M_{CONFIRMED} to the line terminal. Next, the system may attribute small differences between M_{FL} and M_{CONFIRMED} to a minor inaccuracy in the T parameter. An adjusted or refined T parameter may be found per Equation 6 below in all cases except where m≈0.5.

$$T = \frac{Δ t}{2 {m}_{CONFIRMED} - 1} \qquad Eq . 6$$

The system may store data for many past faults and associated confirmed locations. For each fault, M_{FL(k)}, the system may have stored a confirmed location M_{CONFIRMED(k)} and the measured time difference, Δt₍ₖ₎. The system may calculate a refined T parameter that minimizes the error between the locations calculated using T and Δt₍ₖ₎, and the confirmed location M_{CONFIRMED(k)}. For example, the system may identify a T that minimizes the objective function J in Equation 7 below:

$$J ( T ) = {\sum }_{k = 1}^{N} {[ {M}_{CONFIRMED ( k )} - \frac{1}{2} ( 1 + \frac{Δ {t}_{( k )}}{T} ) ]}^{2} \qquad Eq . 7$$

Each time a fault occurs, and its location is confirmed, the system may use Equation 7 to identify a refined T parameter that minimizes the differences between the calculated fault locations and the confirmed fault locations. In some embodiments, the differences between M_{FL} and M_{CONFIRMED} that exceed a threshold value may be attributed to errors other than inaccuracies in T and omitted from the dataset used for optimization. In such cases, the large error may be reported for human analysis and consideration.

In some embodiments, the T parameter may have been reliably and accurately measured. In such instances, the system may treat the initial T parameter, T₀, as a reliable first order approximation and prevent subsequent automatic calibration, or prevent adjustments to the t parameter beyond a small threshold amount or small percentage.

As previously described, some fault locators may provide a physical location, M, rather than a per-unit location, m, using Equation 1, for example. In such embodiments, the system may utilize a datastore of calculated fault locations M_{FL} and confirmed fault locations M_{CONFIRMED} to identify a pair of T and L parameters for use in Equation 1 (or Equation 2 if a single-ended fault locator is used). T and L parameters may be identified to minimize the objective function H in Equation 8 below:

$$H ( T , L ) = {\sum }_{k = 1}^{N} {[ {M}_{CONFIRMED ( k )} - \frac{L}{2} ( 1 + \frac{Δ {t}_{( k )}}{T} ) ]}^{2} \qquad Eq . 8$$

Again, only data points that show a small discrepancy between the calculated and confirmed locations are used and, when reliable first order approximations or measured values are available, T and L are limited to minor calibration refinements not to exceed threshold values.

A wide variety of known optimization and solving algorithms may be employed and, in some embodiments, outlier data may be discarded. In some embodiments, a confidence factor can be associated with each confirmed fault location. The crew can judge, on a scale between 0 and 1, their level of confidence that the discovered markings and sign of damage were caused by the fault in question. This confidence factor, Cₖ, can be used as a weighting coefficient in the equations above. For example, Equation 9 would become:

$$H ( T , L ) = {\sum }_{k = 1}^{N} {{C}_{k} [ {M}_{CONFIRMED ( k )} - \frac{L}{2} ( 1 + \frac{Δ {t}_{( k )}}{T} ) ]}^{2} \qquad Eq . 9$$

In some embodiments, the single value of T (or T and L for physical distance calculations) may be replaced with multiple seasonal values. For example, the system may minimize the objective functions represented in Equations (7) or (8) separately for different environmental conditions, and obtain unique T (or T and L) values for these different environmental conditions. The possible granularity is unlimited, but possible examples could include using different values for hot/warm/cold days or winter season with possible ice buildup on the conductors vs summer season without any ice buildup. Subsequent calibration could be applied only to those values whose operational conditions correspond to the operational conditions in which the fault occurred. Accordingly, the system avoids averaging changes in the parameter T due to operating conditions, but instead tracks unique values of T for various conditions separately, at any level of desired granularity.

As previously described, the system may map tower positions on the per-unit distance scale to facilitate converting between per-unit fault location calculations and real-world physical distances to a fault. A fault locator may identify a fault location, m_{FL}, using, for example, Equation 4 or 5 using an accurately measured or refined T parameter. A crew may confirm the location of a fault, m_{FL}, at a tower that has the per unit location of mₓ according to the utility record. The tower location, mₓ, may be only slightly different than the fault location, m_{FL}, on the per-unit scale. For example, mₓ may be within a few tower spans of m_{FL} on a map of tower locations on the per-unit scale. The difference between m_{FL} and mₓ may be attributable to a fault locator error independent of any length considerations, such as an error due to a noise. The difference between m_{FL} and mₓ may be also be attributable to an error in the assumed location of the tower on the map of tower locations on the per-unit scale. That is, the fault is correctly found to be at fault location, m_{FL}, but the tower per-unit position mₓ is inaccurate and should be adjusted such that mₓ=m_{FL}. Acknowledging that some errors may be due to noise or other non-length-based considerations, the system may reposition the tower in question using Equation 10 below:

mₓ₁=mₓ₀+α·(m_{FL}−mₓ₀) Eq. 10

In Equation 10, mₓ₀ represents the old or initial position of the tower on the per-unit scale and mₓ₁ represents the new position of the tower on the per-unit scale. A weighting factor α, can be selected to control the degree of repositioning. In some embodiments, the weighting factor may be selected based on the crew confidence in the confirmed fault location.

In FIG. 4, only the tower with the confirmed fault location is repositioned from an initial position 450 to a refined position 451 based on the confirmed fault location 475.

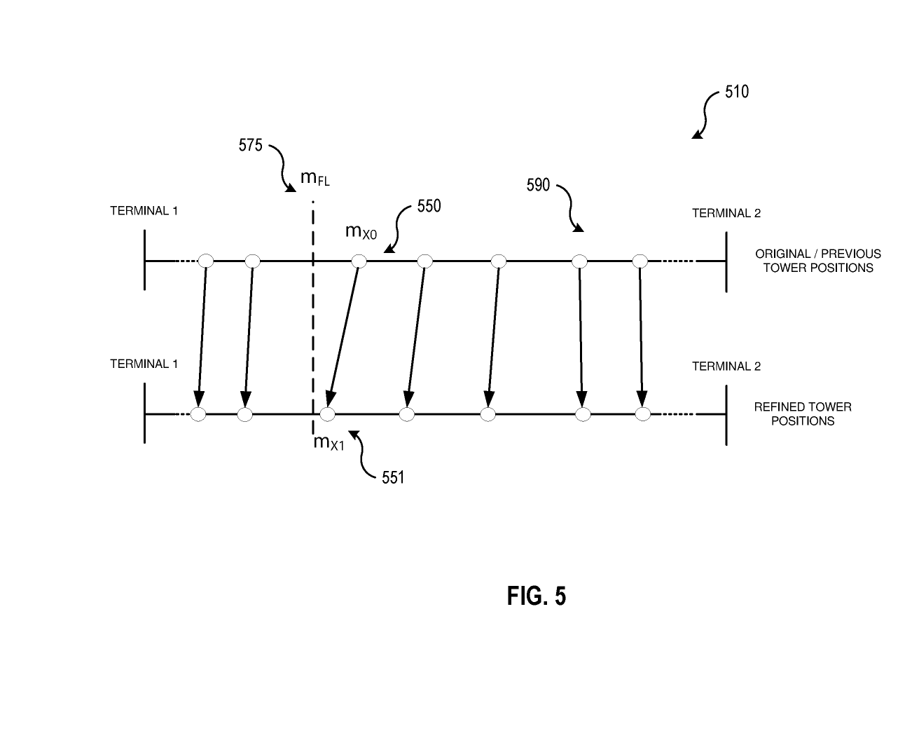

In contrast, FIG. 5 illustrates a per-unit mapping of tower locations 510 in which the tower with the confirmed fault is moved from an initial location 550 to a refined location 551 and adjacent towers are repositioned as well in proportion to their distance from the tower with the confirmed fault at the location 575. As illustrated, towers 590 are not repositioned because they are too distant from the fault location 575.

The amount of repositioning that each tower undergoes may be nonlinearly related to the distance each tower is from the fault location 575. Towers that are very distant from the fault location 575 may move very little or not at all. Neighboring towers may be moved proportionally to their distance from the tower with the confirmed fault 575.

As the system experiences faults over the years, more and more towers will be slightly “repositioned” on the per-unit scale. The system will continually improve the mapping between per-unit electrical output values from the fault locator and the actionable tower positions.

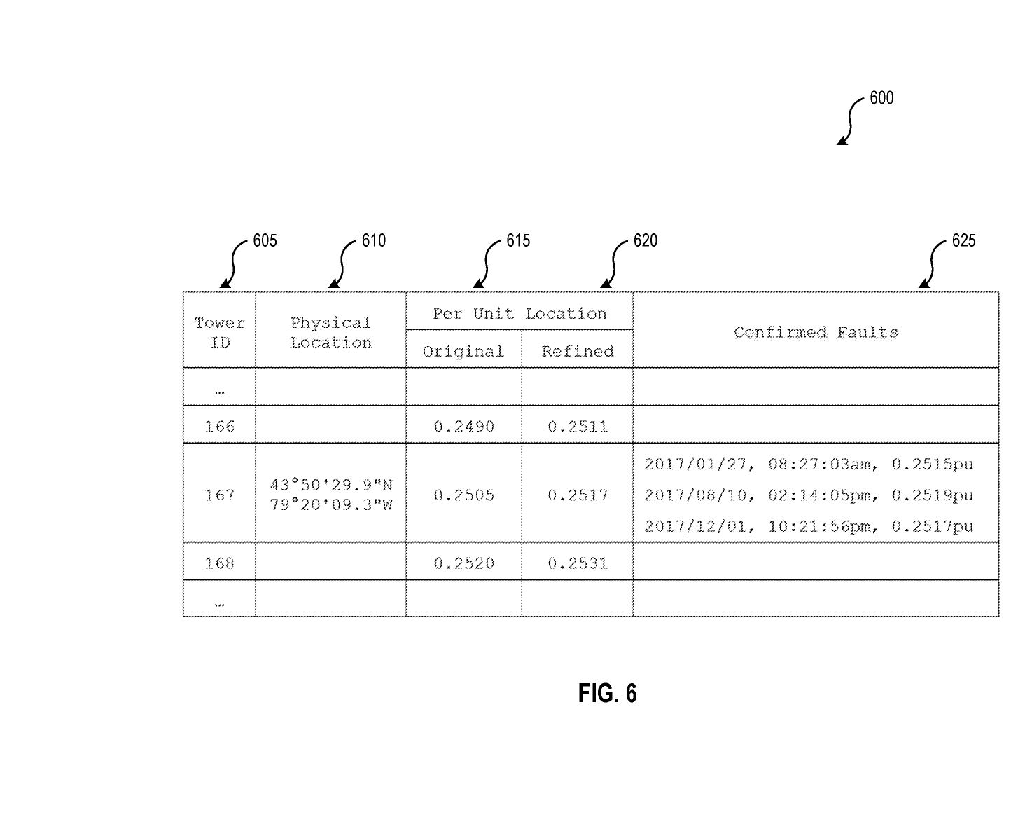

FIG. 6 illustrates an example table 600 of tower IDs 605, physical location 610, and per-unit distances before 615 and after 620 refinement based on confirmed faults 625. The tower IDs 605 may identify each tower to distinguish it from other towers. The physical locations 610 may be GPS coordinates, distances from landmarks, or other real-world locations. The original or prior per-unit distances 615 may be displayed along with refined per-unit distances 620 based on confirmed faults 625. In the illustrated embodiment, the per-unit location of the tower 166 and tower 168 have been refined. Of course, the physical locations of the towers do not change.

The original per-unit locations 615 may have been created as part of a best-effort translation of the physical location data 610 into per-unit distance using, for example, measured distances d3 (FIG. 2) on a two-dimensional map or d2 (FIG. 2) using a three-dimensional map. The confirmed fault data 625 may include additional information, such as the date and time of each fault, per-unit fault location as calculated by a fault locator, date and time of inspection, crew or lineman identifier, confidence level, etc. The systems and methods described herein provide for a continual refining of a mapping between per-unit locations and physical locations. The system allows the line crews to express the physical locations of the towers in whatever distance format they may choose.

FIG. 6 includes a tower with a tower ID 167 located at GPS coordinates 43° 50′29.9″N; 79° 20′09.3″W. The initial per-unit position of this tower was approximated as 0.2505 per-unit. Three faults were found on this tower during a period of time. These faults were located by the fault locator at 0.2515 per-unit, 0.2519 per-unit, and 0.2517 per-unit. Per Equation 10, the per-unit position of this tower has moved from the original 0.2505 per-unit to 0.2517 per-unit.

Using the original per-unit locations of the towers, at 615, a fault located at 0.2518 per-unit would have been suspected to be at (mapped to) tower 168. However, using the refined tower locations, at 620, the fault located at 0.2518 per-unit will now be suspected to be at (mapped to) tower 167.

The systems and methods for automatic calibration of T and L parameters and the systems and methods for automatic re-mapping or map refinement of per-unit tower locations can be used independently, in combination, or in sequence. For example, the first few confirmed faults can be used to calibrate or refine the T parameter. After that, the autocalibration of the T parameter may be suspended and subsequent faults are used to refine the mapping of per-unit tower locations. Periodically, autocalibration of the T parameter may resume.

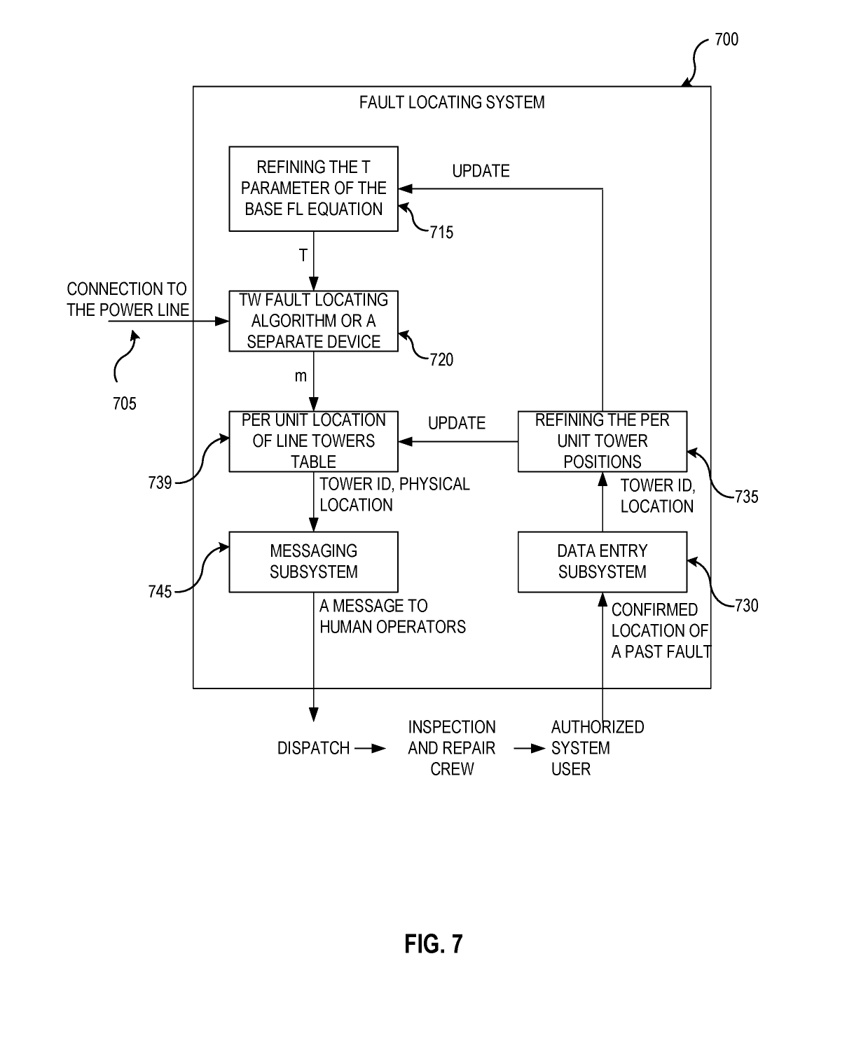

FIG. 7 illustrates a functional block diagram 700 of a fault location system that uses confirmed fault locations as feedback to refine parameters and/or tower locations on a per-unit scale. A fault locator may implement a traveling wave fault detection algorithm to identify a fault location in terms of per-unit line length, at 720. A table, one-dimensional graph, or other mapping of towers to the per-unit scale may be used to identify a tower corresponding to the fault location, at 739. A messaging subsystem may covey the physical location of the tower (e.g., GPS) to human operators, at 745.

The dispatched human operator may enter various information regarding the fault via a data entry subsystem 730, including a confirmed location of the fault. The confirmed location of the fault may be used, at 735, to update the table or other mapping of towers on the per-unit scale, 735 to 739. Alternatively, or additionally, the confirmed location of the fault may be used, 735 to 715, to refine the T parameter by the fault locators, at 715. Subsequent faults on the powerline, at 705, may be processed by the fault locator implementing the traveling wave fault detection algorithm, at 720, using the refined T parameter for increased accuracy. Subsequent identification of a tower using the mapping of towers on the per-unit scale may use the refined tower locations to improve mapping accuracy.

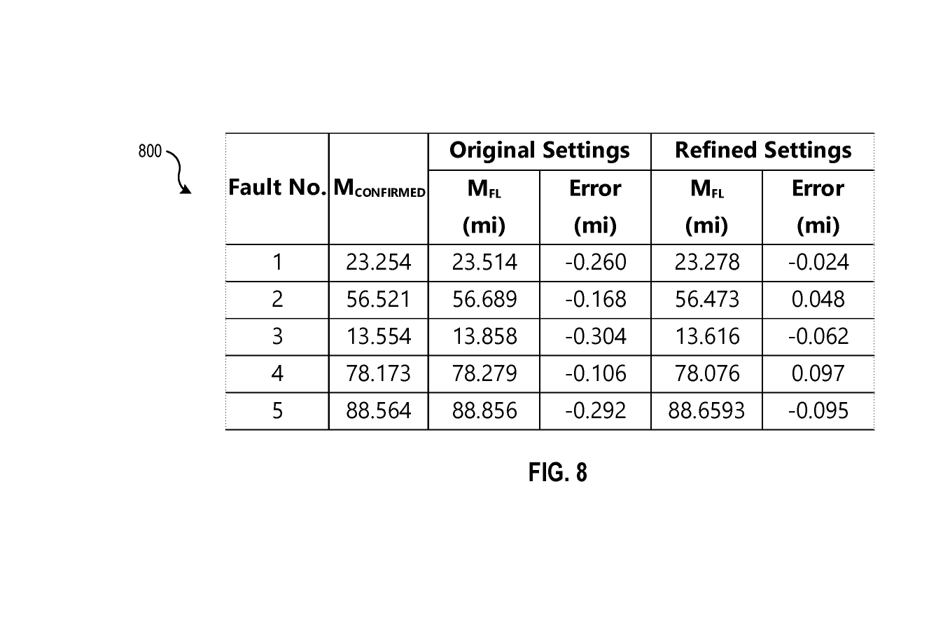

FIG. 8 illustrates an example table 800 of historical fault data calculated by an IED programmed with a T parameter value of 548 μs for a 100-mile line. The table 800 includes data for the confirmed location, M_{CONFIRMED}, of five historical faults. The reported location of the fault, M_{FL}, based on the original settings, is shown along with an error value. The penultimate column shows the distance to the fault location that an IED would have reported if refined T parameter and line length parameters were used based on a minimization of Equation 9. The last column shows the improved (lower) error of each reported fault location using the refined physical line property parameters (e.g., the T parameter and line length parameters).

The last column shows the improved (lower) error of each reported fault location using the refined physical line property parameters (e.g., the T and L parameters). The preceding example may provide for continual adjustment to the T parameter and line length parameters to ensure that values are used for future fault calculations that would have minimized past errors (i.e., minimize the difference between historical reported (M_{FL}) and actual (M_{CONFIRMED}) fault location values). In many installations, the continued collection of fault data will increasingly refine the T parameter and line length parameters to minimize or eliminate any significant difference between the reported and actual fault location values. An IED may report fault location values as distance values relative to the electrical line length of the conductor from the relay that received the traveling waves caused by the fault. In some embodiments, the actual fault location values, M_{CONFIRMED}, may be provided by line crews using another one of the plurality of distance measurement types (e.g., line-of-sight distance, straight-line distance, or terrain-distance). In such embodiments, the discrepancy between the reported and actual fault location values may be due, at least in part, to the different “distance” measurements being used. However, assuming a linear or near-linear relationship between the various distance types, the proposed systems and methods will still produce increasingly “accurate” fault location predictions from the perspective of the line technicians.

Returning to FIG. 8, it is shown that the refined T parameter and L parameter reduce the total error squared from 0.2843 miles² to 0.0252 miles² for all five historical faults.

In some embodiments, the system and methods described herein may be used to adjust the assumed locations of tower positions based on a comparison of reported (M_{FL}) and actual (M_{CONFIRMED}) fault location values. Another practical approach for improving the accuracy of fault location information given to line crews looking for faults is to provide a more accurate mapping between reported fault locations, M_{FL}, and the identification tag of the tower found to actually have the fault. This mapping is effectively a mapping between the linear distance-to-fault indication and the geospatial tower locations, e.g., the GPS coordinates of line towers. This mapping can be programmed as a post-processing task in SCADA software and/or implemented by local, remote, or supervisory IEDs.

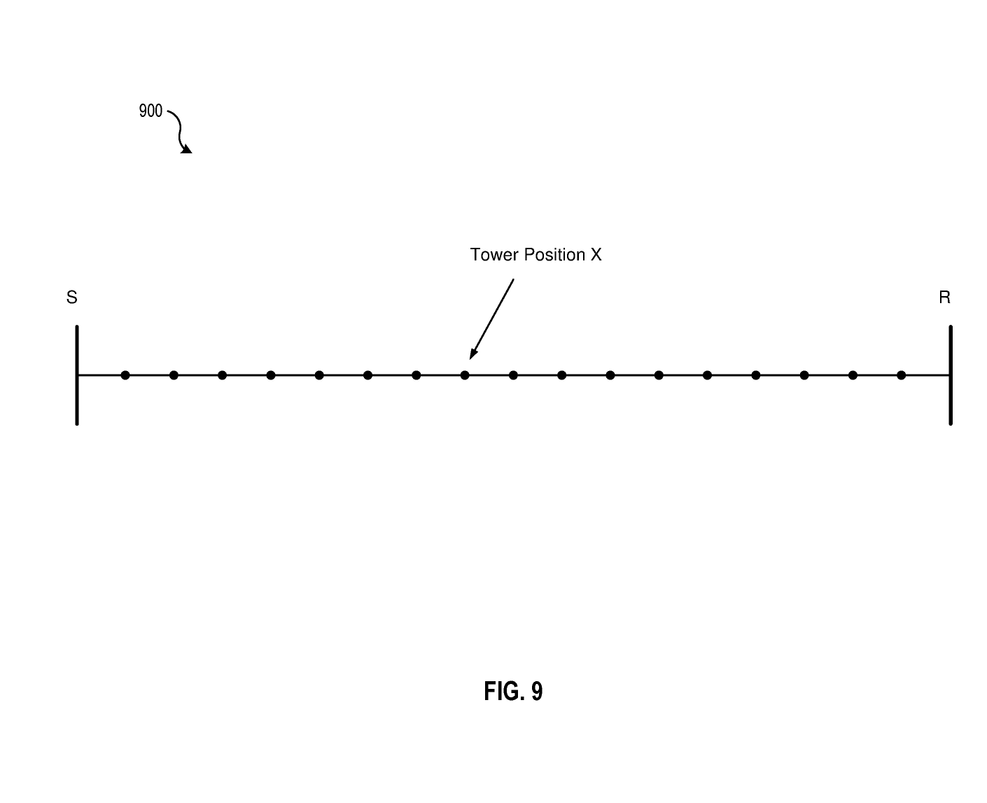

FIG. 9 illustrates a simplified one-line representation of an electric powerline 900 with representations of tower positions on the line as dot markers between terminal S and terminal R. Initially, markers may be placed representing the per-unit location of each tower relative to one of the line terminals S and R. The per-unit positional data of each tower may be adjusted to minimize the discrepancy between the tower location predicted to have a fault by an IED and the tower determined to actually have the fault by a technician or line crew.

For example, if the fault locator reported a distance of M₁ for a line fault, while the line crew found the fault at a tower nominally located at M₀ on the one-dimensional line graph, and M₀ and M₁ are relatively close, the tower position may be modified in, for example, the SCADA software from M₀ to a new location closer to the confirmed location of M₁ (or even all the way to the location of M₁ in some embodiments). An IED may calculate the new tower position using Equation 10 above.

The coefficient, a, may be selected to achieve a desired learning “speed” between 0 (no learning) and 1 (aggressive learning). That is, set to 0, the location information of towers will not be updated at all. Set to 1, the location information of a tower will be repositioned to the location at which the fault was actually found by the technicians.

A selection between 0 and 1 will reposition the tower closer to the position at which the actual fault was found. As a specific example, with α=0.25, the tower may be repositioned by one quarter of the distance between the old position and the new position corresponding to the confirmed fault location. In some embodiments, once a given tower has been effectively repositioned from a previously known position to a new position, all towers between the tower in question and the nearest confirmed location (another fault-confirmed tower, a line terminal, or a line tap) may be proportionally repositioned.

As an example, an IED may utilize a double-ended traveling wave-based fault-locating technique to report a fault location at a distance of 10.935 miles from a terminal traveling wave detector. A line crew may use the reported fault location to narrow their search and find the fault at a tower located at a distance of 11.054 miles from the terminal traveling wave detector.

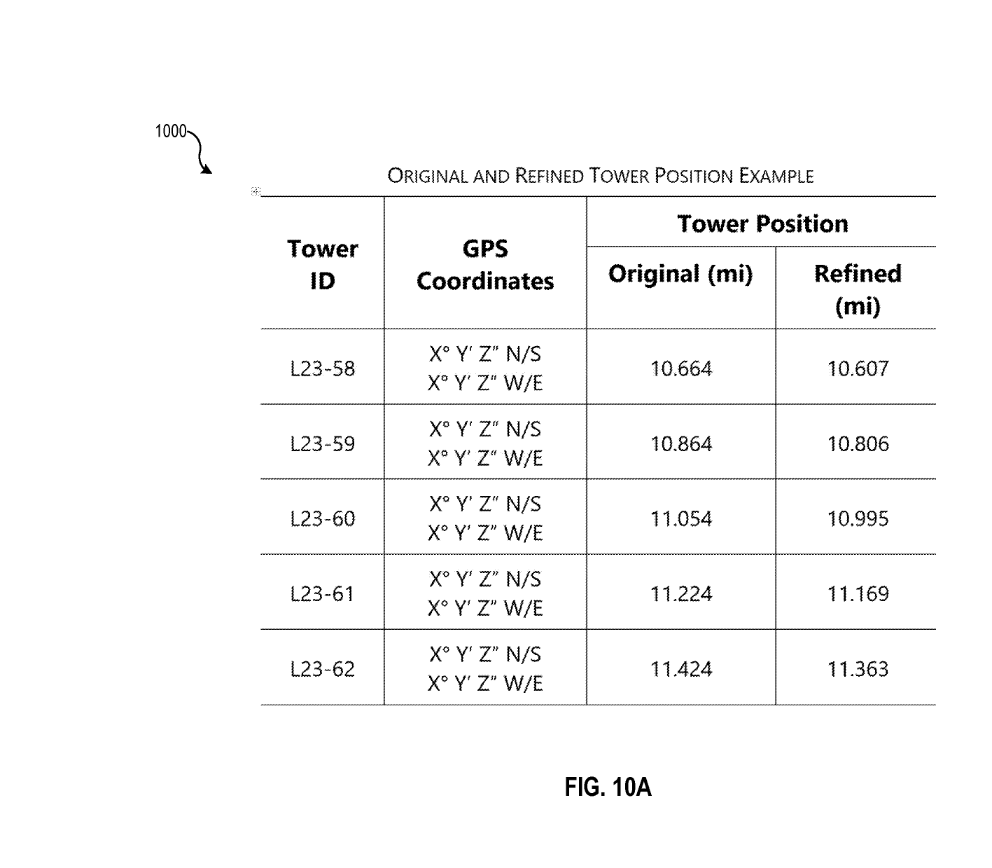

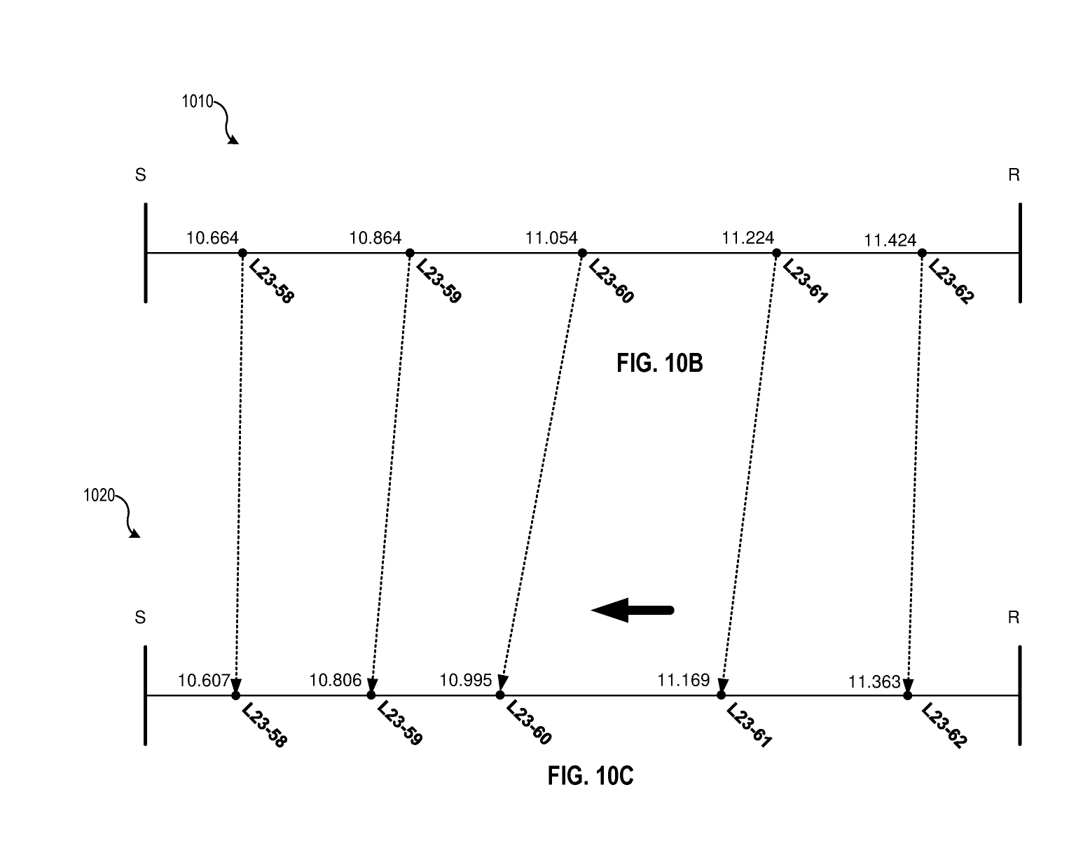

FIG. 10A illustrates an example table 1000 of original and refined tower positions. The original tower positions include a middle tower, L23-60, at the distance of 11.054 miles, corresponding to the tower found by the line crew in the example above. Using a learning coefficient, a, of 0.5, the refined tower position will be updated in the table 1000 half way between the original tower position at a distance of 11.054 miles and the reported tower position at a distance of 10.935. The refined tower position, as shown in FIG. 10A, is 10.995 miles.

Assuming that the nearest confirmed location to the identified tower is the local terminal, all the tower positions located between the reported tower position and the local terminal may be updated. In one approach, the small correction, based on the learning coefficient, a, may be divided among all the tower spans between the tower in question and the line terminal. In a different approach, only the tower identified by the technicians as having the actual fault is repositioned. In still other embodiments, neighboring towers may be repositioned by a smaller percentage of the learning coefficient, a, while the other towers may be left at their nominal positions.

In yet another approach, all the towers may be repositioned proportionally to their distance from the line terminal and the learning coefficient, a, selected between 0 and 1. As an example, the location of each tower may be repositioned by, for example, a ratio of the reported position and the original position (e.g., by multiplying the current position by 10.995/11.054, or 0.99466, in this example). The positions of all the towers toward the other terminal may also be updated accordingly using one of the three approaches outlined above.

FIG. 10A shows an example of a fragment of a tower position table 1000 for the example above. The tower positions have been multiplied by a constant that reflects the change in the position of tower L23-60. Towers close to tower L23-60 are repositioned more than the towers that are further from tower L23-60. Towers close to the line terminals are repositioned only slightly relative to their nominal positions. Each tower is repositioned by a small fraction of their distance to the line terminal. FIG. 10B illustrates a simplified diagram 1010 of tower positions based on original or default position data in the table of FIG. 10A. FIG. 10C illustrates an exaggerated diagram 1020 of the repositioned tower locations corresponding to the data in the table of FIG. 10B.

While specific embodiments and applications of the disclosure have been illustrated and described, the disclosure is not limited to the precise configurations and components disclosed herein. The scope of the present disclosure should, therefore, be interpreted to encompass at least the following claims:

1. An auto-calibrating fault detection system, comprising:
a datastore to store at least one physical parameter of a powerline;
a traveling wave-based fault detection system to calculate fault location information based, at least in part, on:
arrival times of traveling waves from the detected fault, and
the at least one stored physical parameter of the powerline;
a reporting system to generate a fault location report based on the calculated fault location information; and
a calibration subsystem to
receive a confirmed location of the fault, and
adjust the stored physical parameter based on a difference between the calculated location of the fault and the confirmed location of the fault.

2. The system of claim 1, wherein the at least one physical parameter of the powerline comprises a line length parameter (L parameter).

3. The system of claim 1, wherein the at least one physical parameter of the powerline comprises a traveling wave line propagation time parameter (T-parameter).

4. The system of claim 1, wherein the reporting system is configured to generate a fault location report identifying one of:
a calculated per-unit distance to the fault;
a calculated physical distance to the fault; and
estimated GPS coordinates of the fault based on the calculated distance.

5. The system of claim 1, wherein the reporting system is configured to generate a fault location report identifying a tower determined to be located closest to the fault.

6. A method comprising:
mapping initial tower locations of each of a plurality of towers on a per-unit scale of a powerline supported by the plurality of towers;
calculating, via a traveling wave-based fault locator, a per-unit location of a first fault on the powerline; and
reporting one of the plurality of towers as being mapped closest to calculated per-unit location of the first fault.

7. The method of claim 6, wherein reporting the tower comprises reporting GPS coordinates associated with the identified tower.

8. The method of claim 6, wherein reporting the tower comprises reporting a map-based distance from one of:
a landmark to the reported tower, and
a powerline terminal to the reported tower.

9. The method of claim 6, further comprising:
receiving identification of a tower confirmed to be associated with the first fault; and
adjusting the per-unit mapped location of the confirmed tower to be closer to the calculated per-unit location of the first fault.

10. The method of claim 9, wherein the confirmed tower associated with the first fault is the same as the reported tower.

11. The method of claim 6, further comprising:
receiving identification of a tower confirmed to be associated with the first fault; and
adjusting the per-unit mapped locations of multiple towers, including the confirmed tower, based on the calculated per-unit location of the first fault.

12. The method of claim 6, further comprising:
receiving identification of a tower confirmed to be associated with the first fault that is different than the reported tower; and
adjusting the per-unit mapped locations of multiple towers by amounts sufficient to ensure that the confirmed tower is mapped closest to the calculated per-unit location of the first fault, while preserving the order of the mapped towers.

13. The method of claim 12, wherein the mapped location of each of the multiple towers is adjusted by an amount proportional to a distance each respective tower is currently mapped from the calculated per-unit location of the first fault.

14. The method of claim 6, further comprising:
receiving a confirmed identification of a tower associated with the first fault; and
adjusting the per-unit mapped location of each of the plurality of towers by an amount proportional to a distance from which each tower is currently mapped relative to the confirmed per-unit location of the first fault, such that the tower confirmed to be associated with the first fault is mapped closer to the calculated per-unit location of the fault and the order of the mapped towers is preserved.

15. The method of claim 14, wherein adjusting the per-unit mapped location of the tower confirmed to be associated with the first fault comprises re-mapping its location to be equal to the calculated per-unit location of the fault.

16. The method of claim 6, further comprising:
receiving identification of a tower confirmed to be associated with the first fault;
adjusting the per-unit mapped locations of a multiple towers, including the confirmed tower, to preserve the order of the towers and adjust the mapped location of the confirmed tower to be closer to the calculated per-unit fault location;
calculating, via the traveling wave-based fault locator, a per-unit location of a second fault on the powerline; and
reporting one of the plurality of towers as being mapped closest to calculated per-unit location of the second fault based on the adjusted per-unit mapped locations.

17. A method, comprising:
storing an initial traveling wave line propagation time parameter (T parameter) associated with a powerline;
determining an operational condition associated with the powerline;
adjusting the T parameter based on the determined operational condition;
calculating a distance to a detected fault based on:
arrival times of one or more traveling waves from the detected fault, and the adjusted T-parameter; and
reporting information for locating the detected fault based on the calculated distance to the detected fault.

18. The method of claim 17, further comprising:
receiving confirmed location information of the detected fault; and
adjusting the T-parameter based on the difference between the calculated distance to the detected fault and the confirmed location information of the detected fault.

19. The method of claim 18, further comprising:
determining a change in the operational condition associated with the powerline;
adjusting the T parameter further based on the changed operational condition.

20. The method of claim 19, further comprising:
calculating a distance to a second detected fault based on:
arrival times of a second set of traveling waves from the second detected fault, and
the multiple-adjusted T-parameter; and
reporting information for locating the second detected fault based on the calculated distance to the second detected fault.
